(19) United States
(12) Patent Application Publication
(10) Pub. No.: US 2022/0406789 A1
(43) Pub. Date: Dec. 22, 2022

(54) SEMICONDUCTOR DEVICE AND METHOD FOR FABRICATING THE SAME

(71) Applicant: SK hynix Inc., Gyeonggi-do (KR)

(72) Inventors: Jin Hwan JEON, Gyeonggi-do (KR); Dae Won KIM, Gyeonggi-do (KR); Tae Kyun KIM, Gyeonggi-do (KR); Jung Woo PARK, Gyeonggi-do (KR); Sung Hwan AHN, Gyeonggi-do (KR); Su Ock CHUNG, Gyeonggi-do (KR); Dong Goo CHOI, Gyeonggi-do (KR)

(21) Appl. No.: 17/562,838

(22) Filed: Dec. 27, 2021

(30) Foreign Application Priority Data
Jun. 18, 2021 (KR) 10-2021-0079260

(51) Int. Cl. H01L 27/108; H01L 21/768; H01L 21/308

(52) U.S. Cl. CPC H01L 27/10885; H01L 21/76843; H01L 21/76897; H01L 21/3086

(57) ABSTRACT

Present invention is related to a semiconductor device with an improved reliability and a method for the same. A method for fabricating a semiconductor device according to an embodiment of the present invention may comprise: forming a plurality of bit line structures over a substrate; forming line-shaped openings between the bit line structures; forming a stopper structure on edges of the line-shaped openings; filling a line pattern in each of the line-shaped openings; forming a plurality of contact plugs and a plurality of isolation grooves by etching the line patterns; and filling a plug isolation layer in the isolation grooves.

### CROSS-REFERENCE TO RELATED APPLICATIONS

The present application claims priority to Korean Patent Application No. 10-2021-0079260, filed on Jun. 18, 2021, which is incorporated herein by reference in its entirety.

### BACKGROUND

### 1. Field

Various embodiments of the present invention relate to a semiconductor device and, more particularly, to a semiconductor device including a stopper structure and a method for fabricating the same.

### 2. Description of the Related Art

A dielectric material is formed between neighboring pattern structures in a semiconductor device. As semiconductor devices are being highly integrated, distance between pattern structures is decreasing. Therefore, parasitic capacitance has increased.

Performance of a semiconductor device decreases as parasitic capacitance increases. As a result, improved structures are needed for maintaining and further improving the reliability of the semiconductor devices.

### SUMMARY

Various embodiments of the present invention provide a semiconductor device with improved reliability and a method for fabricating the same.

A semiconductor device according to an embodiment of the present invention may comprise: a substrate including a cell array region and a cell array edge region; a plurality of bit line structures formed over the cell array region of the substrate; a stopper structure formed over the cell array edge region of the substrate; a plurality of storage node contact plugs formed between the bit line structures of the cell array region; and a dummy plug formed on the stopper structure.

A method for fabricating a semiconductor memory device according to an embodiment of the present invention may comprise: forming a plurality of bit line structures over a substrate; forming line-shaped openings between the bit line structures; forming a stopper structure on edges of the line-shaped openings; filling a line pattern in each of the line-shaped openings; forming a plurality of contact plugs and a plurality of isolation grooves by etching the line patterns; and filling a plug isolation layer in the isolation grooves.

A semiconductor device according to an embodiment of the present invention may comprise: a plurality of bit line structures, each including a bit line contact plug formed on a substrate, a bit line formed on the bit line contact plug, and a bit line hard mask formed on the bit line contact plug; a plurality of storage node contact plugs formed between the bit line structures over a cell array region of the substrate; a plurality of plug isolation layers, wherein each plug isolation layer is disposed between a pair of adjacent storage node contact plugs; a stopper structure formed over a cell array edge region of the substrate; a plurality of dummy plugs formed over the cell array edge region of the substrate separated by another plurality of plug isolation layers, wherein the stopper structure is at a higher level than a bottom surface of the plurality of storage node contact plugs.

The present invention may prevent etch defect of storage node contact plugs by forming a stopper structure at a cell array edge region.

These and other features of the present invention will become better understood with the following figures and detailed description.

### BRIEF DESCRIPTION OF THE DRAWINGS

FIG. 1A is a plan view illustrating a semiconductor device according to an embodiment of the present invention.

FIG. 1B is a cross-sectional view taken along the line A-A′ of FIG. 1A.

FIGS. 2A to 2N are diagrams illustrating a method for fabricating a semiconductor device according to an embodiment of the present invention.

### DETAILED DESCRIPTION

Various embodiments described herein will be described with reference to cross-sectional views, plan views and block diagrams, which are ideal schematic views of the present invention. Therefore, the structures of the drawings may be modified by fabricating technology and/or tolerances. Various embodiments of the present invention are not limited to the specific structures shown in the drawings, but include any changes in the structures that may be produced according to the fabricating process. Also, any regions and shapes of regions illustrated in the drawings with schematic views are intended to illustrate specific examples of structures of regions of the various elements, and are not intended to limit the scope of the invention.

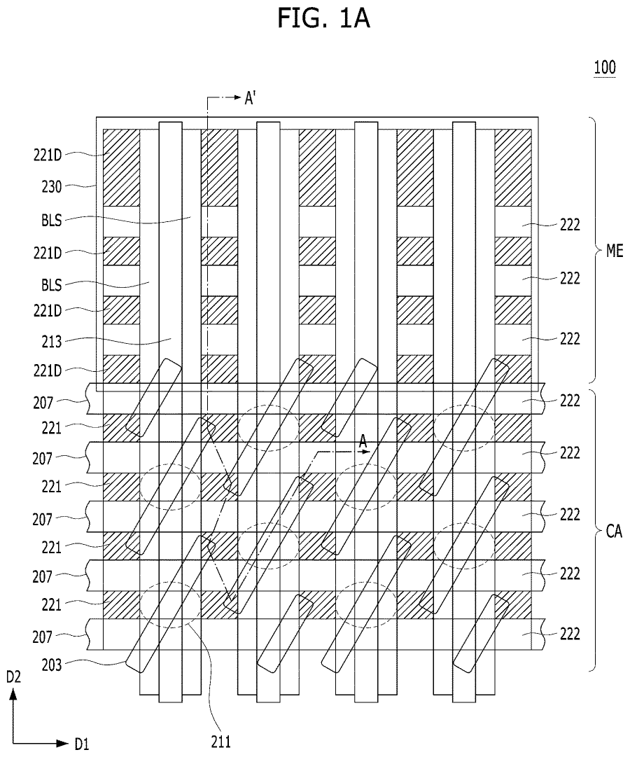

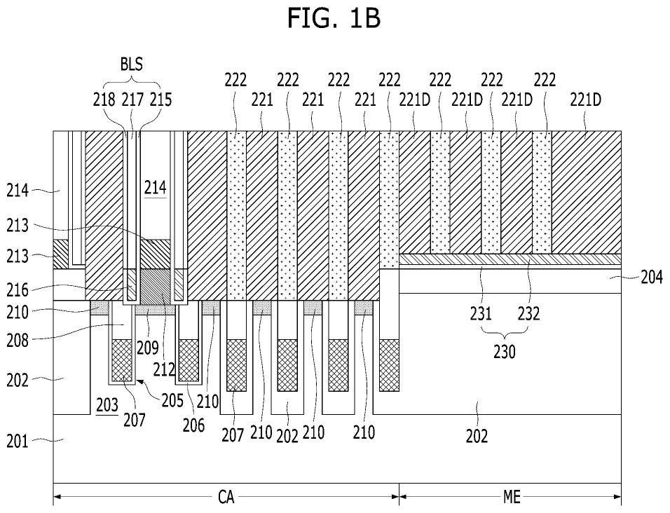

FIG. 1A is a plan view illustrating a semiconductor device according to an embodiment of the present invention. FIG. 1B is a cross-sectional view taken along the line A-A′ of FIG. 1A.

Referring to FIGS. 1A to 1B, a semiconductor device 100 may include a plurality of memory cells. Each memory cell may include a cell transistor including a buried word line 207 and a bit line 213.

The semiconductor device 100 will be described in detail below.

A device isolation layer 202 and an active region 203 may be formed in a substrate 201. A plurality of active regions 203 may be defined by the device isolation layer 202. The substrate 201 may be made of a suitable material for semiconductor processing. The substrate 201 may include a semiconductor substrate. The substrate 201 may be formed of a silicon-containing material. The substrate 201 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 201 may include other semiconductor materials such as germanium. The substrate 201 may include a III/V group semiconductor substrate, for example, a compound semiconductor substrate such as GaAs. The substrate 201 may include a silicon on insulator (SOI) substrate. The device isolation layer 202 may be formed through an STI (Shallow Trench Isolation) process.

A gate trench 205 may be formed in the substrate 201. A gate dielectric layer 206 may be formed conformally on the bottom surface and side surface of the gate trench 205. A buried word line 207 may be formed on the gate dielectric layer 206. The buried word line 207 may partially fill a lower portion of the gate trench 205 on the gate dielectric layer 206. A gate capping layer 208 may be formed on the buried word line 207. An upper surface of the buried word line 207 may be disposed at a lower level than an upper surface of the substrate 201. The buried word line 207 may be formed of a metal material having a low resistivity. The buried word line 207 may be formed by sequentially stacking titanium nitride (TiN) and tungsten (W). In another embodiment, the buried word line 207 may be formed of only titanium nitride. The buried word line 207 may also be referred to as a “buried gate electrode.” The buried word line 207 may extend along its length axis in a first direction D1.

First and second impurity regions 209 and 210 may be formed in the substrate 201. The first and second impurity regions 209 and 210 may be spaced apart from each other by the gate trench 205. The first and second impurity regions 209 and 210 may also be referred to as a “source/drain region.” The first and second impurity regions 209 and 210 may include an N-type impurity such as arsenic (As) or phosphorus (P). The buried word line 207 and the first and second impurity regions 209 and 210 may form a cell transistor. A short channel effect of a cell transistor may be improved by the buried word line 207.

A bit line contact plug 212 may be formed on the substrate 201. The bit line contact plug 212 may be formed on the first impurity region 209. The bit line contact plug 212 may be disposed inside a bit line contact hole 211. The bit line contact hole 211 may penetrate through a hard mask layer 204 formed over the substrate 201 and extend into the substrate 201. The hard mask layer 204 may be formed over the substrate 201. The hard mask layer 204 may include a dielectric material. The bit line contact hole 211 may expose the first impurity region 209. A lower surface of the bit line contact plug 212 may be disposed at a lower level than an upper surface of the device isolation layer 202 and an upper surface of the active region 203. The bit line contact plug 212 may be formed of polysilicon or a metal material. A portion of the bit line contact plug 212 may have a line width smaller than a diameter of the bit line contact hole 211. A bit line 213 may be formed over the bit line contact plug 212. A bit line hard mask 214 may be formed over the bit line 213. A stack structure of the bit line contact plug 212, the bit line 213, and the bit line hard mask 214 may also be referred to as a “bit line structure.” The bit line 213 may have a line shape extending in a second direction D2 intersecting with the buried word line 207. A portion of the bit line 213 may connect to the bit line contact plug 212. Line widths of the bit line 213 and the bit line contact plug 212 may be the same in the first direction. Therefore, the bit line 213 may cover the bit line contact plug 212 and extend in the second direction D2. The bit line hard mask 214 may include a dielectric material such as silicon nitride.

A spacer structure BLS may be formed on a sidewall of the bit line structure. The spacer structure BLS may be extended to be disposed on a sidewall of the bit line contact plug 212. For example, the spacer structure BLS on both sidewalls of the bit line 213 may include first, second, and third spacers 215, 217, and 218. The spacer structure BLS of the bit line contact plug 212 may include the first spacer 215 and a gap-fill spacer 216. The spacer structure BLS may include silicon nitride, silicon oxide, low-k material, or a combination thereof. The low-k material may include silicon boron nitride (SiBN), silicon carbon oxide (SiCO), silicon carbon nitride (SiCN), silicon boron nitride (SiBCN), or a combination thereof. The first spacer 215 and the gap-fill spacer 216 may include silicon nitride, and the second spacer 217 may include silicon oxide or a low-k material. In another embodiment, the spacer structure BLS may include a multi-layered spacer including NKON, NKNAN, NKOK, NKOKN, NKAKN, KOK, or KAK, wherein N refers to silicon nitride, K refers to a low-k material, O refers to silicon oxide, and A refers to an air gap. In another embodiment, the outermost spacer of the spacer structure BLS may include a low-k material.

A storage node contact plug 221 may be formed between neighboring bit line structures. The storage node contact plug 221 may be connected to the second impurity region 210. The storage node contact plug 221 may include polysilicon, metal nitride, a metal material, metal silicide, or a combination thereof. In some embodiments, the storage node contact plug 221 may be formed by sequentially stacking polysilicon, cobalt silicide, and tungsten.

A plug isolation layer 222 may be formed between neighboring storage node contact plugs 221 when viewed from a direction parallel to the bit line structure. The plug isolation layer 222 may be formed between neighboring bit line structures. The storage node contact plugs 221, which are adject to each other along the second direction D2, may be spaced apart by the storage node contact plugs 221. A plurality of plug isolation layers 222 and a plurality of storage node contact plugs 221 may be alternately disposed along the second direction D2 between neighboring bit line structures. The storage node contact plug 221 may directly contact the third spacer 218 of the spacer structure BLS, and the third spacer 218 may include a low-k material.

A memory element (not shown) may be formed over the storage node contact plug 221. The memory element may include a capacitor including a storage node. The storage node may include a pillar type storage node. The storage node may also include a cylinder type, or a combination of a cylinder type and a pillar type storage node.

Although not shown, a dielectric layer and a plate node may be formed over the storage node.

The plug isolation layer 222 may include silicon nitride or a low-k material. In case that the plug isolation layer 222 includes a low-k material, a parasitic capacitance between neighboring storage node contact plugs 221 with the plug isolation layer 222 interposed therebetween may be reduced. The plug isolation layer 222 may include SiCO, SiCN, SiOCN, SiBN, or SiBCN.

According to FIGS. 1A and 1B, the semiconductor device 100 may include a cell array region CA and a cell array edge region ME. A plurality of storage node contact plugs 221 may be formed in the cell array region CA, and a plurality of dummy plugs 221D may be formed in the cell array edge region ME. Stopper structures 230 may be disposed below the dummy plugs 221D. The cell array edge region ME may refer to an edge of the cell array region CA. Also, the cell array edge region ME may refer to a boundary region between the cell array region CA and the peripheral circuit region (not shown). The cell array region CA may be a cell mat region, and the cell array edge area ME may be a cell mat edge region.

A bottom surface of the storage node contact plugs 221 may be disposed at a lower level than a bottom surface of the dummy plugs 221D. A leveling structure may be formed by forming the stopper structures 230 below the dummy plugs 221D. As will be described below, the storage node contact plug 221 and the dummy plug 221D may be formed simultaneously. For example, the storage node contact plug 221 and the dummy plug 221D may be simultaneously formed by forming and etching line-shaped polysilicon layers in the cell array region CA and the cell array edge region ME.

As described above, etching difficulty for forming the storage node contact plug 221 and the dummy plug 221D may be reduced and etch defects may be prevented by forming the stopper structures 230 in the cell array edge region ME.

The stopper structures 230 may be formed of the same material as a portion of the spacer structure BLS. For example, the stopper structure 230 may include silicon nitride, silicon oxide, or a combination thereof. After forming a spacer structure BLS of multi-layered structure of silicon nitride and silicon oxide, the silicon nitride or silicon oxide may partially remain without being etched by using a mask layer and may be used to form the stopper structures 230. In this embodiment, the stopper structure 230 may include a stack of a first stopper 231 and a second stopper 232. The first and second stoppers 231 and 232 may include silicon nitride. The first stopper 231 and the first spacer 215 may be formed of the same material, for example silicon nitride. The second stopper 232 and the gap-gill spacer 216 may be formed of the same material, for example silicon nitride.

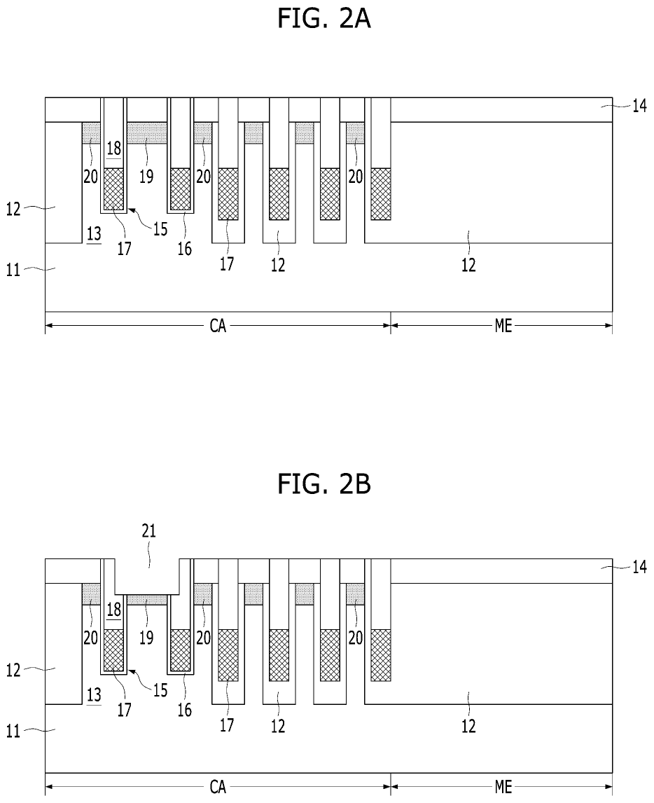

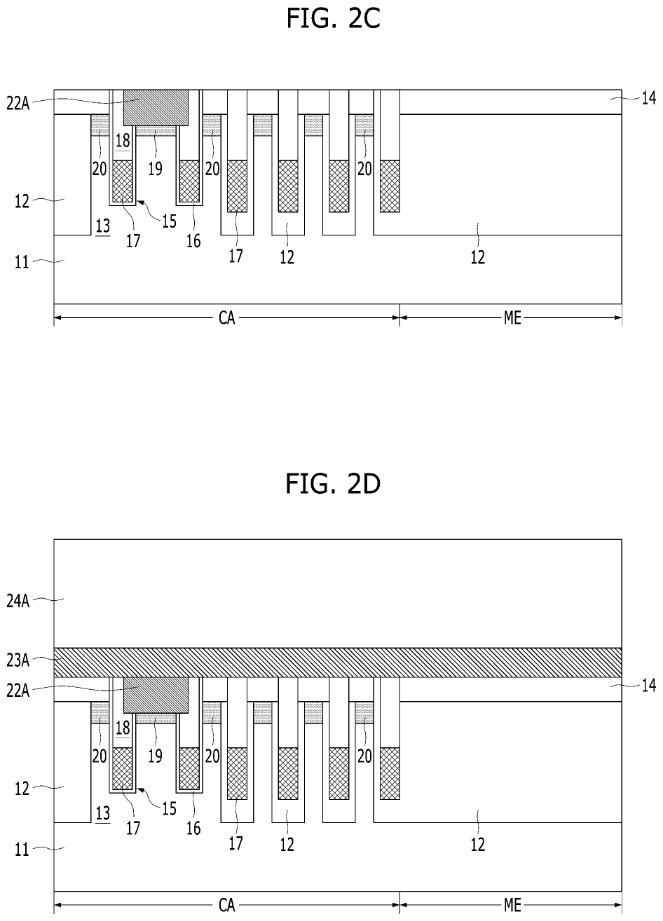

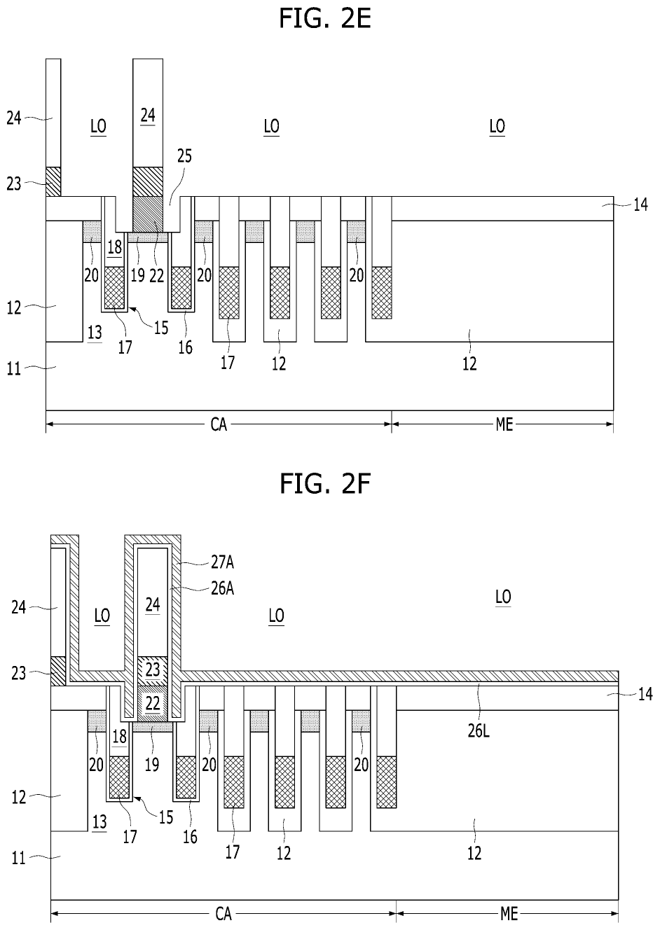

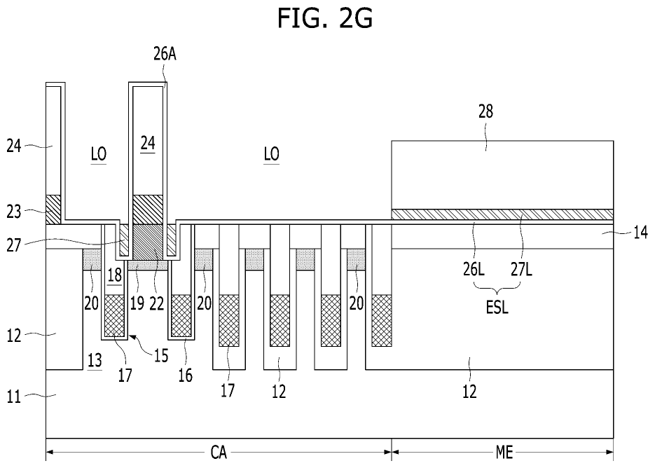

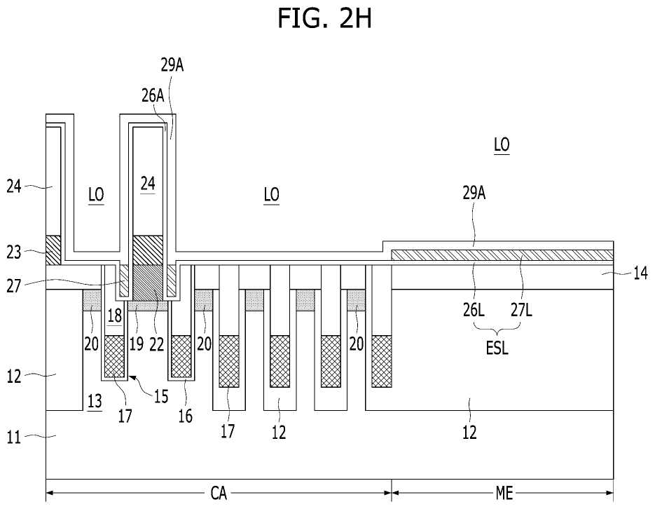

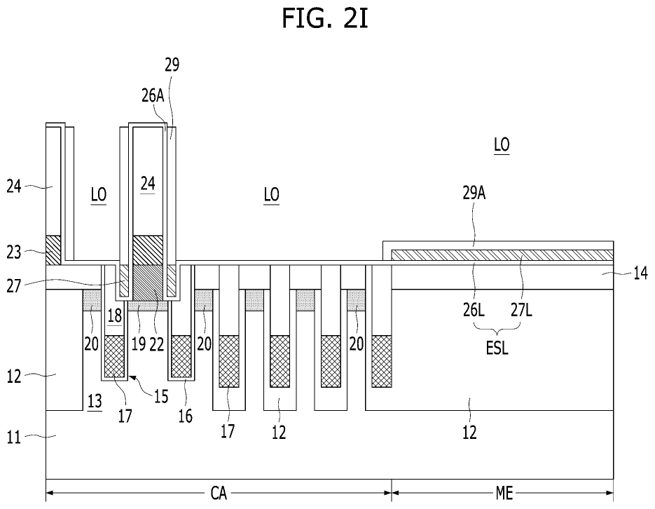

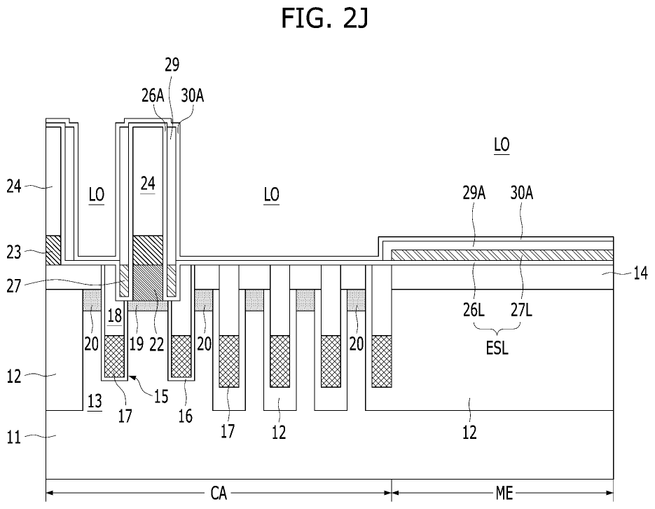

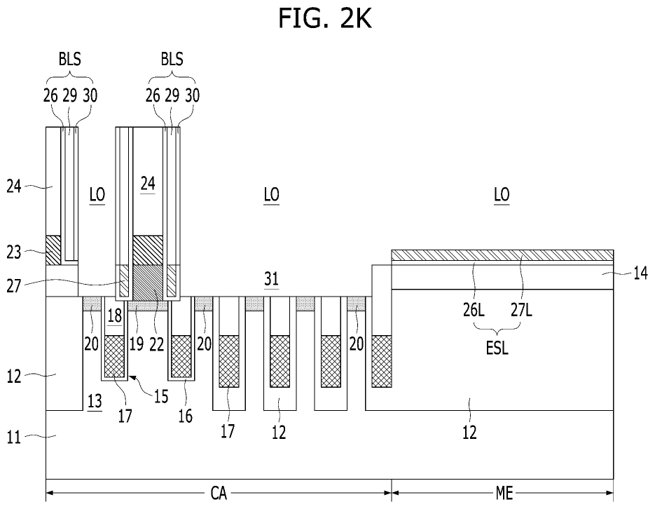

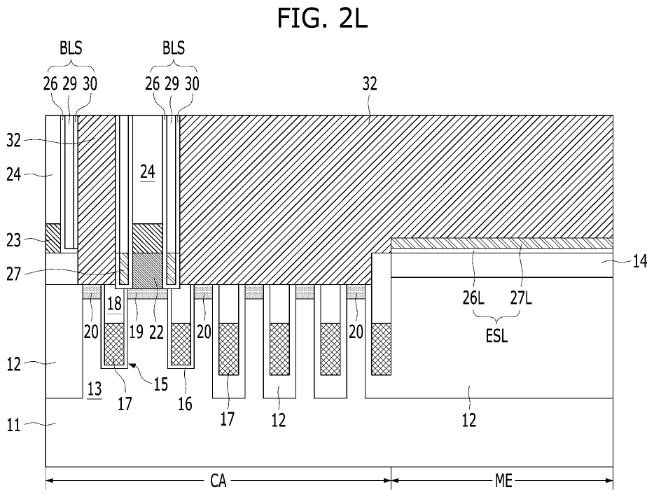

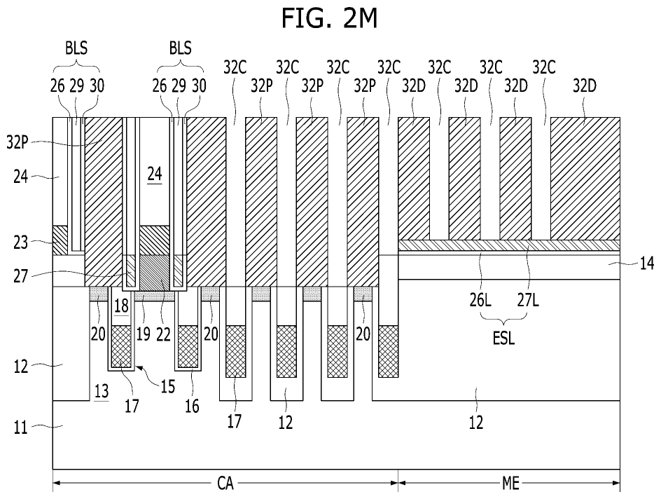

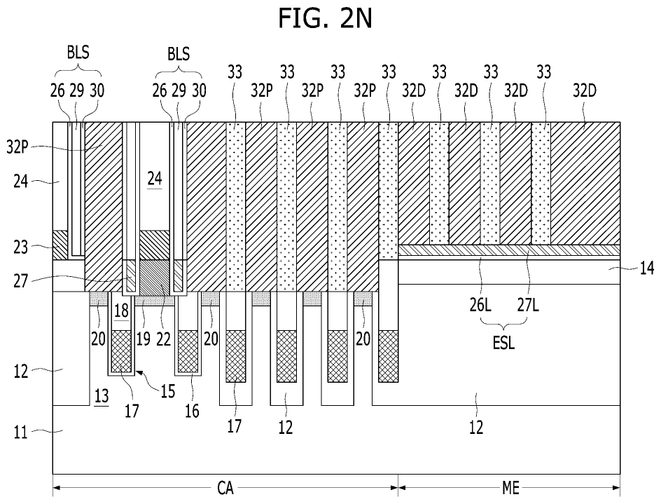

FIGS. 2A to 2N are diagrams illustrating a method for fabricating a semiconductor device according to an embodiment of the present invention. FIGS. 2A to 2N illustrate the fabrication method based on the cross-sectional view taken along the line A-A′ of FIG. 1A.

As shown in FIG. 2A, a device isolation layer 12 may be formed in a substrate 11. The substrate 11 may include a cell array region CA and a cell array edge region ME. A plurality of active regions 13 may be defined by the device isolation layer 12. The device isolation layer 12 may be formed by an STI (Shallow Trench Isolation) process. The STI process may be as follows. An isolation trench (reference numeral omitted) is formed by etching the substrate 11. The isolation trench is filled with a dielectric material, and thus the device isolation layer 12 is formed. The device isolation layer 12 may include silicon oxide, silicon nitride, or a combination thereof. Chemical vapor deposition or other deposition processes may be used for filling the isolation trench with a dielectric material. At least one planarization process, such as, chemical-mechanical polishing (CMP) may be used.

Next, a buried word line structure may be formed in the substrate 11. The buried word line structure may include a gate trench 15, a gate dielectric layer 16 conformally covering the bottom surface and the sidewall of the gate trench 15, a buried word line 17 partially filling a lower part of the gate trench 15 on the gate dielectric layer 16, and a gate capping layer 18 formed on the buried word line 17.

A method for forming the buried word line structure may be as follows.

First, a gate trench 15 may be formed in the substrate 11. The gate trench 15 may have a line shape crossing the active regions 13 and the device isolation layer 12. The gate trench 15 may be formed by an etching process which includes forming a mask pattern (not shown) on the substrate 11 and using the mask pattern as an etching mask. To form the gate trench 15, the hard mask layer 14 may be used as an etch barrier. The hard mask layer 14 may have a shape patterned by a mask pattern. The hard mask layer 14 may include silicon oxide. The hard mask layer 14 may include tetra ethyl ortho silicate (TEOS). The bottom of the gate trench 15 may be at a higher level than the bottom of the device isolation layer 12.

Although not shown, a portion of the isolation layer 12 may be recessed to protrude the active region 13 disposed below the gate trench 15. For example, the device isolation layer 12 disposed below the gate trench 15 may be selectively recessed along the length direction of the gate trench 15. Accordingly, a fin region (reference numeral omitted) may be formed under the gate trench 15. The fin region may be a part of the channel region.

Next, a gate dielectric layer 16 may be formed on the bottom surface and the sidewall of the gate trench 15. Before the gate dielectric layer 16 is formed, etch damage on the surface of the gate trench 15 may be cured. For example, a sacrificial oxide may be formed and removed through thermal oxidation treatment.

The gate dielectric layer 16 may be formed by a thermal oxidation process. For example, the gate dielectric layer 16 may be formed by oxidizing the bottom surface and the sidewall of the gate trench 15.

In another embodiment, the gate dielectric layer 16 may be formed by a deposition method such as chemical vapor deposition (CVD) or atomic layer deposition (ALD). The gate dielectric layer 16 may include a high-k material, oxide, nitride, oxynitride, or a combination thereof. The high-k material may include a hafnium-containing material. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, and a combination thereof.

In another embodiment, the gate dielectric layer 16 may be formed by depositing a liner polysilicon layer and then radically oxidizing the liner polysilicon layer.

In yet another embodiment, the gate dielectric layer 16 may be formed by forming a liner silicon nitride layer and then radically oxidizing the liner silicon nitride layer after.

Next, a buried word line 17 may be formed on the gate dielectric layer 16. To form the buried word line 17, a recessing process may be performed after a conductive layer (not shown) is formed to fill the gate trench 15. The recessing process may be performed by an etchback process or a chemical mechanical polishing (CMP) process followed by an etchback process. The buried word line 17 may have a recessed shape partially filling the gate trench 15. That is, the upper surface of the buried word line 17 may be at a lower level than the upper surface of the active region 13. The buried word line 17 may include a metal, a metal nitride, or a combination thereof. For example, the buried word line 17 may be formed of a titanium nitride (TiN), tungsten (W), or a titanium nitride/tungsten (TiN/W) stack. The titanium nitride/tungsten (TiN/W) stack may have a structure in which titanium nitride is conformally formed and then the gate trench 15 is partially filled by the tungsten. The titanium nitride may be used alone as the buried word line 17, and this may also be referred to as a buried word line 17 of “TiN only structure.” A double gate structure of a titanium nitride/tungsten (TiN/W) stack and a polysilicon layer may be used as the buried word line 17.

Next, a gate capping layer 18 may be formed on the buried word line 17. The gate capping layer 18 may include a dielectric material. The remaining portion of the gate trench 15 on the buried word line 17 is filled with the gate capping layer 18. The gate capping layer 18 may include silicon nitride. In another embodiment, the gate capping layer 18 may include silicon oxide. In yet another embodiment, the gate capping layer 18 may have a Nitride-Oxide-Nitride (NON) structure. The upper surface of the gate capping layer 18 may be at the same level as the upper surface of the hard mask layer 14. To this end, a chemical mechanical polishing (CMP) process may be performed when the gate capping layer 18 is formed.

After the gate capping layer 18 is formed, impurity regions 19 and 20 may be formed. The impurity regions 19 and 20 may be formed by a doping process such as ion implantation. The impurity regions 19 and 20 may include a first impurity region 19 and a second impurity region 20. The first and second impurity regions 19 and 20 may be doped with impurities of the same conductivity type. The first and second impurity regions 19 and 20 may have the same depth. In another embodiment, the first impurity region 19 may be deeper than the second impurity region 20. The first and second impurity regions 19 and 20 may also be referred to as source/drain regions. The first impurity region 19 may be a region to which a bit line contact plug is to be connected, and the second impurity region 20 may be a region to which a storage node contact plug is to be connected. The first impurity region 19 and the second impurity region 20 may be disposed in different active regions 13. Also, the first impurity region 19 and the second impurity region 20 may be disposed in respective active regions 13 while being spaced apart from each other by the gate trenches 15.

A cell transistor of the memory cell may be formed by the buried word line 17 and the first and second impurity regions 19 and 20.

As shown in FIG. 2B, a bit line contact hole 21 may be formed. The hard mask layer 14 may be etched using a contact mask (not shown) to form the bit line contact hole 21. The bit line contact hole 21 may have a circular shape or an elliptical shape when viewed in a plan view. A portion of the substrate 11 may be exposed through the bit line contact hole 21. The bit line contact hole 21 may have a diameter controlled by a predetermined line width. The bit line contact hole 21 may have a shape exposing a portion of the active region 13. For example, the first impurity region 19 may be exposed by the bit line contact hole 21. The bit line contact hole 21 may have a diameter greater than the width of the minor axis of the active region 13. Accordingly, the first impurity region 19, the device isolation layer 12, and the gate capping layer 18 may be partially etched during the etching process for forming the bit line contact hole 21. That is, the gate capping layer 18, the first impurity region 19, and the device isolation layer 12 under the bit line contact hole 21 may be recessed to a predetermined depth. Accordingly, the bottom of the bit line contact hole 21 may be extended into the substrate 11. As the bit line contact hole 21 expands, the surface of the first impurity region 19 may be recessed, and the upper surface of the first impurity region 19 may be positioned at a level lower than the upper surface of the active region 13.

As shown in FIG. 2C, a pre-plug 22A may be formed. The pre-plug 22A may be formed through selective epitaxial growth (SEG). For example, the pre-plug 22A may include an epitaxial layer doped with phosphorus, for example SEG SiP. In this way, the pre-plug 22A may be formed without having a void through the selective epitaxial growth. In another embodiment, the pre-plug 22A may be formed by depositing a polysilicon layer and performing a CMP process on the polysilicon layer. The pre-plug 22A may fill the bit line contact hole 21. The upper surface of the pre-plug 22A may be at the same level as the upper surface of the hard mask layer 14.

As shown in FIG. 2D, a bit line conductive layer 23A and a bit line hard mask layer 24A may be stacked. The bit line conductive layer 23A and the bit line hard mask layer 24A may be sequentially stacked on the pre-plug 22A and the hard mask layer 14. The bit line conductive layer 23A may include a metal-containing material. The bit line conductive layer 23A may include a metal, a metal nitride, a metal silicide, or a combination thereof. In this embodiment, the bit line conductive layer 23A may include tungsten (W). In another embodiment, the bit line conductive layer 23A may include a stack of titanium nitride and tungsten (TiN/W). In this case, the titanium nitride may serve as a barrier. The bit line hard mask layer 24A may be formed of an insulating material having an etch selectivity with respect to the bit line conductive layer 23A and the pre-plug 22A.

The bit line hard mask layer 24A may include silicon oxide or silicon nitride. In this embodiment, the bit line hard mask layer 24A may be formed of silicon nitride.

As shown in FIG. 2E, a bit line structure may be formed. The bit line structure may include a stack of a bit line contact plug 22, a bit line 23, and bit line hard mask 24. The bit line contact plug 22, the bit line 23, and the bit line hard mask 24 may be formed by an etching process using a bit line mask layer (not shown).

The bit line hard mask layer 24A and the bit line conductive layer 23A are etched using the bit line mask layer as an etch barrier.

Accordingly, the bit line 23 and the bit line hard mask 24 may be formed. The bit line 23 may be formed by etching the bit line conductive layer 23A. The bit line hard mask 24 may be formed by etching the bit line hard mask layer 24A.

Subsequently, the pre-plug 22A may be etched to have the same line width as the bit line 23. Accordingly, the bit line contact plug 22 may be formed. The bit line contact plug 22 may be formed over the first impurity region 19. The bit line contact plug 22 may interconnect the first impurity region 19 and the bit line 23. The bit line contact plug 22 may be formed in the bit line contact hole 21. The line width of the bit line contact plug 22 is smaller than the diameter of the bit line contact hole 21. Accordingly, gaps 25 may be defined on both sides of the bit line contact plug 22.

As described above, a gap 25 is formed in the bit line contact hole 21 as the bit line contact plug 22 is formed. This is because the bit line contact plug 22 is formed to be smaller than the diameter of the bit line contact hole 21. The gap 25 is not formed to surround the bit line contact plug 22, but is independently formed on both sidewalls of the bit line contact plug 22. As a result, one bit line contact plug 22 and a pair of gaps 25 are positioned in the bit line contact hole 21, and the pair of gaps 25 are spaced apart from each other by the bit line contact plug 22. A bottom surface of the gap 25 may extend into the device isolation layer 12. The bottom surface of the gap 25 may be at a level lower than the recessed upper surface of the first impurity region 19.

A structure in which the bit line contact plug 22, the bit line 23, and the bit line hard mask 24 are sequentially stacked may also be referred to as a bit line structure. When viewed from top, the bit line structure may be a line-shaped pattern structure extending in any one direction.

A line-shaped opening LO may be defined between adjacent bit line structures. The line-shaped opening LO may be parallel to the bit line structures. The hard mask layer 14 may be exposed by the line-shaped opening LO. The line-shaped opening LO may extend from the cell array region CA to the cell array edge region ME. The hard mask layer 14 of the cell array edge region ME may also be exposed by the line-shaped opening LO.

As shown in FIG. 2F, a first spacer layer 26A may be formed on the bit line structures. The first spacer layer 26A may cover both side walls of the bit line contact plug 22 and side walls of the bit line 23. The first spacer layer 26A may cover both side walls and an upper surface of the bit line hard mask 24. The first spacer layer 26A may include an insulating material. In this embodiment, the first spacer layer 26A may include silicon nitride.

A second spacer layer 27A may be formed on the first spacer layer 26A. The second spacer layer 27A and the first spacer layer 26A may be formed of the same material. The second spacer layer 27A may include silicon nitride. The second spacer layer 27A may be conformally formed on the first spacer layer 26A disposed on top and side surfaces of the bit line structures. The second spacer layer 27A may fill the gaps 25 at both sides of the bit line contact plug 22.

A first spacer layer 26A and a second spacer layer 27A may be formed in the cell array edge region ME. For example, the first spacer layer 26A and the second spacer layer 27A may extend from the cell array region CA to the cell array edge region ME.

As shown in FIG. 2G, a mask layer 28 may be formed. The mask layer 28 may mask the cell array edge region ME. The mask layer 28 may include a photoresist pattern. The second spacer layer 27A of the cell array region CA may be selectively exposed by the mask layer 28.

Next, the second spacer layer 27A may be selectively etched. For example, the second spacer layer 27A may be trimmed to fill the gap 25 at both sides of the bit line contact plug 22. Accordingly, the second spacer layer 27 may remain in the gap 25 on both sides of the bit line contact plug 22, and the second spacer layer 27A may not remain on the first spacer layer 26A on both sides of the bit line 23. The second spacer layer 27A may remain in the cell array edge region

ME.

The second spacer layer filling the gap 25 is abbreviated as “gap-fill spacer 27,” and the second spacer layer remaining in the cell array edge region is abbreviated as “stop liner 27L.” The first spacer layer 26A may remain below the stop liner 27L. Hereinafter, the first spacer layer remaining in the cell array edge region ME is denoted by reference numeral “26L,” and a stack of the first spacer layer 26L and the stop liner 27L remaining in the cell array edge region ME is referred to as a “stopper structure ESL.”

As shown in FIG. 2H, after the mask layer 28 is removed, a third spacer layer 29A may be formed on the stop liner 27L. The third spacer layer 29A may include silicon oxide. The third spacer layer 29A may be formed in the cell array region CA and the cell array edge region ME. In the cell array region CA, the third spacer layer 29A may be formed on the first spacer layer 26A. In the cell array edge region ME, the third spacer layer 29A may be formed on the stop liner 27L.

As shown in FIG. 2I, the third spacer layer 29A may be etched to form the third spacer 29. An etchback process of the third spacer layer 29A may be performed to form the third spacer 29. The third spacer 29 may cover an upper portion of the gap-fill spacer 27. The third spacer 29 may be positioned on both sidewalls of the bit line 23 with the first spacer layer 26A interposed therebetween. In the cell array edge region ME, the third spacer layer 29A may remain on the stop liner 27L.

As shown in FIG. 2J, a third spacer 29 may be formed. A fourth spacer layer 30A may be formed on the third spacer layer 29A and the third spacer 29. The fourth spacer layer 30A may include silicon nitride.

As shown in FIG. 2K, the fourth spacer layer 30A may be selectively etched to form the fourth spacer 30 on the sidewall of the line-shaped opening LO.

The lower materials may be etched to be self-aligned to the fourth spacer 30. Accordingly, a plurality of recess regions 31 exposing a portion of the active region 13 may be formed between the bit line structures. Anisotropic etching or a combination of anisotropic etching and isotropic etching may be used to form the recess regions 31. For example, the fourth spacer layer 30A and the first spacer layer 26A which are disposed between the bit line structures may be sequentially etched anisotropically, and then an exposed portion of the active region 13 may be isotropically etched. In another embodiment, the hard mask layer 14 may also be isotropically etched. Portions of the active region 13 and the gap-fill spacer 27 may be exposed by the recess regions 31.

The recess regions 31 may extend into the substrate 11. During the formation of the recess regions 31, the device isolation layer 12, the gate capping layer 18, and the second impurity region 20 may be recessed to a predetermined depth. The bottom surfaces of the recess regions 31 may be at a level lower than the top surfaces of the bit line contact plugs 22. The bottom surface of the recess regions 31 may be at a higher level than the bottom surfaces of the bit line contact plugs 22. The line-shaped openings LO and the recess regions 31 may be interconnected. A vertical structure of the line-shaped openings LO and the recess regions 31 may also be referred to as a “storage node contact hole.”

A spacer structure BLS may be formed on a sidewall of the bit line structure by etching the fourth spacer layer 30A and the first spacer layer 26A while the recess regions 31 are formed. The spacer structure BLS may include materials having different dielectric constants.

The spacer structure BLS may include a first spacer 26, a third spacer 29, and a fourth spacer 30. The first spacer 26 may directly contact sidewalls of the bit line contact plug 22 and the bit line 23. The third spacer 29 may cover the first spacer 26, and the fourth spacer 30 may cover the third spacer 29. The first spacer 26 may be positioned between the gap-fill spacer 27 and the bit line contact plug 22. A third spacer 29 may be positioned between the fourth spacer 30 and the first spacer 26.

A first spacer 26, a third spacer 29, and a fourth spacer 30 may be sequentially stacked on a sidewall of the bit line 23. The first spacer 26 and gap-fill spacer 27 may be stacked on a sidewall of the bit line contact plug 22.

As shown in FIG. 2L, line patterns 32 filling each of the line-shaped openings LO may be formed. The line patterns 32 may fill the line-shaped openings LO and the recess regions 31. The line patterns 32 may contact the second impurity regions 20. The line patterns 32 may be disposed adjacent to the bit line structure. When viewed from top, a plurality of line patterns 32 may be positioned between the plurality of bit line structures.

The line patterns 32 may extend to the cell array edge region ME while being formed in the cell array region CA. In the line patterns 32, a leveling structure may be formed in the cell array region CA and the cell array edge region ME by the stopper structure ESL. The leveling structure refers to a structure in which the bottom surfaces of the line patterns 32 formed in the cell array region CA are lower than the bottom surfaces of the line patterns 32 formed in the cell array edge region ME. The subsequent etching process may become easier due to this leveling structure.

As shown in FIG. 2M, the line patterns 32 may be etched by using a mask layer extending in a direction crossing the line patterns 32. Accordingly, a plurality of contact plugs 32P and a plurality of isolation grooves 32C may be formed. When viewed from the top, a plurality of contact plugs 32P may be disposed between adjacent bit line structures, and the isolation grooves 32C may be disposed between the contact plugs 32P. A leveling structure may be formed by the lower stopper structure ESL during the etching process for forming the isolation groove 32C. The contact plugs formed in the cell array edge region ME may be abbreviated as dummy plugs 32D. The bottom surfaces of the dummy plugs 32D and the bottom surfaces of the contact plugs 32P may be located at different levels. For example, the bottom surfaces of the dummy plugs 32D may be at a higher level than the bottom surfaces of the contact plugs 32P.

According to the present embodiment, the etching difficulty for forming the storage node contact plug 221 and the dummy plug 221D may be reduced, and etch defect may be prevented by forming the stopper structure ESL. As the stopper structure ESL is formed, etching may be sufficiently performed to separate the adjacent dummy plugs 221D. Thus, bridging between dummy plugs 221D and storage node contact plugs 221 due to unetched dummy plugs 221D may be prevented. For example, the etching process for forming the dummy plug 221D may be completed before the etching process for forming the storage node contact plug 221 is completed, and thus the neighboring dummy plugs 221D may be completely spaced apart. The lower structures disposed below the dummy plug 221D may be prevented from being etched by the stopper structure ESL until the etching process for forming the storage node contact plug 221 is completed.

As shown in FIG. 2N, plug isolation layers 33 filling the isolation grooves 32C may be formed. To form the plug isolation layers 33, silicon nitride deposition and chemical mechanical polishing (CMP) may be sequentially performed.

Although not shown, a storage node of a capacitor may be subsequently formed on the storage node contact plug 221. In another embodiment, metal silicide and a metal material may be sequentially formed on the etched back storage node contact plug 221 before the storage node of the capacitor is formed and after the storage node contact plug 221 is etched back.

The present invention described above is not limited by the above-described embodiments and the accompanying drawings, and it will be apparent to those skilled in the art that various changes, substitutions, and modifications may be made without departing from the spirit and scope of the present invention.

What is claimed is:

1. A semiconductor device comprising:
a substrate including a cell array region and a cell array edge region;
a plurality of bit line structures formed over the cell array region of the substrate;
a stopper structure formed over the cell array edge region of the substrate;
a plurality of storage node contact plugs formed between the bit line structures of the cell array region; and
a dummy plug formed on the stopper structure.

2. The semiconductor device of claim 1, wherein a bottom surface of the dummy plug is disposed at a higher level than a bottom surface of the storage node contact plugs.

3. The semiconductor device of claim 1, wherein the stopper structure includes silicon nitride, silicon oxide, or a combination thereof.

4. The semiconductor device of claim 1, further including a multi-layered spacer formed on both sidewalls of the bit line structures.

5. The semiconductor device of claim 4, wherein the multi-layered spacer and the stopper structure include a same material.

6. The semiconductor device of claim 1, wherein the bit line structures include a stack structure of a bit line contact plug, a bit line formed on the bit line contact plug, and a bit line hard mask formed on the bit line.

7. The semiconductor device of claim 6, further including:
a first spacer covering a sidewall of the bit line contact plug and a sidewall of the bit line;
a gap-fill spacer disposed on the first spacer over both sidewalls of the bit line contact plug; and
a second spacer disposed on the first spacer and covering both sidewalls of the bit line,
wherein the stopper structure and the gap-fill spacer include a same material.

8. The semiconductor device of claim 7, wherein the gap-fill spacer and the stopper structure include silicon nitride.

9. The semiconductor device of claim 1, wherein the storage node contact plugs and the dummy plug include polysilicon.

10. The semiconductor device of claim 1, further including plug isolation layers between the bit line structures,
wherein the storage node contact plug and the dummy plug are disposed between the plug isolation layers.

11. The semiconductor memory device of claim 10, wherein the plug isolation layers include silicon nitride.

12. A method for fabricating a semiconductor device comprising:
forming a plurality of bit line structures over a substrate;
forming line-shaped openings between the bit line structures;
forming a stopper structure on edges of the line-shaped openings;
filling a line pattern in each of the line-shaped openings;
forming a plurality of contact plugs and a plurality of isolation grooves by etching the line patterns; and
filling a plug isolation layer in the isolation grooves.

13. The method of claim 12, wherein the forming of the stopper structure includes:
forming a spacer layer on the bit line structures;
forming a mask layer covering the edges of the line-shaped openings on the spacer layer; and
etching the spacer layer by using the mask layer for forming the stopper structure remaining on the edges of the line-shaped openings.

14. The method of claim 12, wherein the stopper structure includes silicon nitride, silicon oxide, or a combination thereof.

15. The method of claim 12, wherein the forming of the line-shaped openings between the bit line structures includes:
forming a multi-layered spacer layer on the bit line structures, wherein the stopper structure retains a portion of the multi-layered spacer layer.

16. The method of claim 15, wherein the multi-layered spacer layer and the stopper structure includes a same material.

17. The method of claim 12, wherein the forming of the plurality of contact plugs and the plurality of isolation grooves by etching the line patterns includes:
forming a mask layer extending in a direction intersecting the line patterns; and
etching the line patterns by using the mask layer.

18. The method of claim 12, wherein the substrate includes a cell array region and a cell array edge region, and
wherein the contact plugs include a plurality of storage node contact plugs formed over the cell array region and a plurality of dummy plugs over the cell array edge region.

19. The method of claim 18, wherein the stopper structure is formed over the cell array edge region, and the dummy plug is formed over the stopper structure.
